(19) United States
(12) Patent Application Publication
(10) Pub. No.: US 2026/0351201 A1
(43) Pub. Date: Nov. 5, 2026

(54) DISPLAY DEVICE

(71) Applicant: LG Display Co., Ltd., Seoul (KR)

(72) Inventors: Binn KIM, Paju-si (KR); Dong Yoon KIM, Paju-si (KR)

(21) Appl. No.: 19/660,910

(22) Filed: Apr. 28, 2026

(30) Foreign Application Priority Data
Apr. 30, 2025 (KR) 10-2025-0057090

(51) Int. Cl. G09G 3/3275; G09G 3/3233; H10K 59/131

(52) U.S. Cl. CPC G09G 3/3275; G09G 3/3233; H10K 59/131; G09G 2300/0426; G09G 2300/0842

(57) ABSTRACT

A display device includes a display panel including a plurality of gate lines and a plurality of data lines and at least one data driving integrated circuit configured to supply a data signal to each of the plurality of data lines. Among data lines driven by one data driving integrated circuit, (i) a first set of data lines disposed in a central region are directly connected to the data driving integrated circuit, and (ii) a second set of data lines disposed on left and right sides are not directly connected to the data driving integrated circuit, and are electrically connected, via a plurality of connection lines within an active area, to the first set of data lines.

### CROSS REFERENCE TO RELATED APPLICATIONS

Pursuant to 35 U.S.C. § 119(a), this application claims the benefit of an earlier filing date and right of priority to Korean Patent Application No. 10-2025-0057090, filed on Apr. 30, 2025, the entire content of which is hereby incorporated by reference as if fully set forth herein.

### TECHNICAL FIELD

The present disclosure relates to a display device.

### BACKGROUND

Image display devices that reproduce various information on a screen are a core technology in the era of information and communications, and are being developed to be thinner, lighter, and more portable, and to have higher performance. Therefore, display devices capable of being manufactured in a lightweight and thin form are attracting attention.

Representative examples of display devices include a liquid crystal display (LCD) device, a quantum dot display (QD) device, a field emission display (FED) device, and an organic light emitting diode (OLED) display device.

An OLED display device is a self-emissive display device. Therefore, the OLED display device is advantageous in terms of power consumption due to the low-voltage driving properties thereof, and has excellent color implementation performance, a high response speed, a wide viewing angle, and a high contrast ratio (CR). Thus, the OLED display device is currently being developed as a next-generation display device.

In such an OLED display device, research is being conducted to increase an active area while reducing a bezel area, which is a non-active area.

A display device according to an implementation of the present disclosure includes a display panel including a plurality of gate lines and a plurality of data lines and at least one data driving integrated circuit configured to supply a data signal to each of the plurality of data lines. Among data lines driven by one data driving integrated circuit, (i) a first set of data lines disposed in a central region are directly connected to the data driving integrated circuit, and (ii) a second set of data lines disposed on left and right sides are not directly connected to the data driving integrated circuit, and are electrically connected, via a plurality of connection lines within an active area, to the first set of data lines.

The plurality of connection lines may all have the same length.

The plurality of connection lines may intersect the plurality of data lines in a middle portion of a longitudinal length of the plurality of data lines.

Each of the plurality of connection lines may interconnect data lines implementing the same color.

The first set of data lines disposed in the central region may correspond to half of the plurality of data lines, and the second set of data lines disposed on the left and right sides may correspond to a remaining half of the plurality of data lines.

The first set of data lines consist of (i) first data lines disposed in a region B-1 in the central region and (ii) second data lines disposed in a region B-2 in the central region, and the second set of data lines consist of (i) third data lines disposed in a region A-1 adjacent to the region B-1 and (ii) fourth data lines disposed in a region A-2 adjacent to the region B-2. The third data lines disposed in the region A-1 may be electrically connected to the first data lines disposed in the region B-1 via some of the plurality of connection lines, and the fourth data lines disposed in the region A-2 may be electrically connected to the second data lines disposed in the region B-2 via remaining connection lines among the plurality of connection lines.

The number of third data lines disposed in the region A-1, the number of fourth data lines disposed in the region A-2, the number of first data lines disposed in the region B-1, and the number of second data lines disposed in the region B-2 may be the same.

Data input times of the third data lines disposed in the region A-1 and the fourth data lines disposed in the region A-2 may be longer than data input times of the first data lines disposed in the region B-1 and the second data lines disposed in the region B-2.

A plurality of sub-pixels may be disposed between a (4k-3)^{th} gate line and a (4k-2)^{th} gate line and between a (4k-1)^{th} gate line and a 4k^{th} gate line among the plurality of gate lines, and sub-pixels may not be disposed between the (4k-2)^{th} gate line and the (4k-1)^{th} gate line and between the 4k^{th} gate line and a (4k+1)^{th} gate line among the plurality of gate lines.

Two sub-pixels may be disposed between a pair of data lines and another pair of data lines, and sub-pixels may not be disposed between the pair of data lines and between the other pair of data lines.

Sub-pixels in the region A-1 and the region A-2 may be driven by even-numbered gate lines, and sub-pixels in the region B-1 and the region B-2 may be driven by odd-numbered gate lines.

Sub-pixels in the region A-1 and the region A-2 may be driven by odd-numbered gate lines, and sub-pixels in the region B-1 and the region B-2 may be driven by even-numbered gate lines.

The display device may further include reference voltage lines disposed between the two sub-pixels disposed between the pair of data lines and the other pair of data lines.

A plurality of sub-pixels may be disposed between respective gate lines among the plurality of gate lines. One sub-pixel may be disposed between a (4k-3)^{th} data line and a (4k-2)^{th} data line among the plurality of data lines and between respective gate lines, and one sub-pixel may be disposed between a (4k-1)^{th} data line and a 4k^{th} data line and between respective gate lines. Sub-pixels may not be disposed between the (4k-2)^{th} data line and the (4k-1)^{th} data line and between the 4k^{th} data line and a (4k+1)^{th} data line.

The display device may further include reference voltage lines disposed between the (4k-2)^{th} data line and the (4k-1)^{th} data line and between the 4k^{th} data line and the (4k+1)^{th} data line.

The plurality of connection lines may be formed of the same material as the plurality of gate lines.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

FIG. 1 is a block diagram showing a display device according to an implementation of the present disclosure;

FIG. 2 is a circuit diagram of a pixel included in the display device according to the implementation of the present disclosure;

FIG. 3 is a cross-sectional view of one of sub-pixels disposed in an active area of a display panel according to an implementation of the present disclosure;

FIG. 4 is a plan view showing data lines and a plurality of data driving integrated circuits according to an implementation of the present disclosure;

FIG. 5 is a plan view showing a plurality of data lines driven by one data driving integrated circuit according to an implementation of the present disclosure;

FIG. 6 is a plan view showing RC delay variation in a vertical direction and a horizontal direction of a plurality of data lines driven by one data driving integrated circuit according to an implementation of the present disclosure;

FIG. 7 is a view showing data input times and data charging rates of data lines in a region A and a region B according to an implementation of the present disclosure;

FIG. 8 is a view showing a layout of gate lines, data lines, and sub-pixels in a region A-1 and a region B-1 according to an implementation of the present disclosure;

FIG. 9 is a schematic cross-sectional view taken along the connection line shown in FIG. 8; and

FIG. 10 is a view showing a layout of gate lines, data lines, and sub-pixels in the region A-1 and the region B-1 according to another implementation of the present disclosure.

### DETAILED DESCRIPTION

Implementations of the present disclosure can provide a display device capable of implementing a narrow bezel.

In OLED display devices, a design objective is to reduce the number of data driving integrated circuits that drive data lines, for price competitiveness. However, as the number of data driving integrated circuits is reduced, the number of data lines driven by each data driving integrated circuit increases, and thus a width of a connection wiring region connecting a pad of the data driving integrated circuit to the data lines inevitably increases. Therefore, if the number of data driving integrated circuits is reduced, the bezel area may increase.

Implementations of the present disclosure can provide a display device capable of implementing a narrow bezel even when the number of data driving integrated circuits is reduced.

Additional advantages, aspects, and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description and claims hereof as well as the appended drawings.

Reference will now be made in detail to the exemplary implementations of the present disclosure, examples of which are illustrated in the accompanying drawings. The same or similar elements are denoted by the same reference numerals throughout the specification.

In the following description of the implementations of the present disclosure, a detailed description of known functions and configurations incorporated herein will be omitted when it may make the subject matter of the present disclosure rather unclear. Further, the names of elements used in the following description of the implementations of the present disclosure are selected in consideration of ease of preparation of the specification, and may thus differ from the names of parts of an actual product.

The shapes, sizes, ratios, angles and numbers of elements given in the drawings to describe the implementations of the present disclosure are merely exemplary, and thus, the present disclosure is not limited to the illustrated details.

In the following description of the implementations, the terms “including”, “comprising,” and “having” are to be interpreted as indicating the presence of one or more other characteristics, numbers, steps, operations, elements or parts stated in the specification or combinations thereof, and do not exclude the presence of other characteristics, numbers, steps, operations, elements, parts or combinations thereof, or the possibility of adding the same, unless the term “only” is used. It will be understood that a singular expression of an element encompasses a plural expression unless stated otherwise.

In the interpretation of elements included in the various implementations of the present disclosure, it is to be interpreted that quantitative descriptions of characteristics of the elements include error ranges unless stated otherwise.

In the following description of the implementations, it will be understood that, when positional relationships are expressed, for example, when an element is said to be “on,” “above,” “under,” or “beside” another element, the two elements may directly contact each other, or one or more other elements may be interposed between the two elements, unless the term “just” or “directly” is used.

In the following description of the implementations, it will be understood that, when temporal relationships are expressed, for example, when terms expressing a sequence of events, such as “after,” “subsequent to,” “next,” and “before” are used, the terms encompass both a continuous relationship between the events and a discontinuous relationship between the events, unless the term “just” or “directly” is used.

In the following description of the implementations, it will be understood that, when the terms “first,” “second,” etc. are used to describe various elements, these terms are used merely to distinguish the same or similar elements. Therefore, a first element described hereinafter could be termed a second element without departing from the technical scope of the disclosure.

Respective features of the various implementations of the present disclosure may be partially or wholly coupled to or combined with each other and be interlocked or driven in various technical manners, and the respective implementations may be implemented independently of each other or may be implemented together through connection therebetween.

Hereinafter, a display device according to an implementation of the present disclosure will be described with reference to the accompanying drawings.

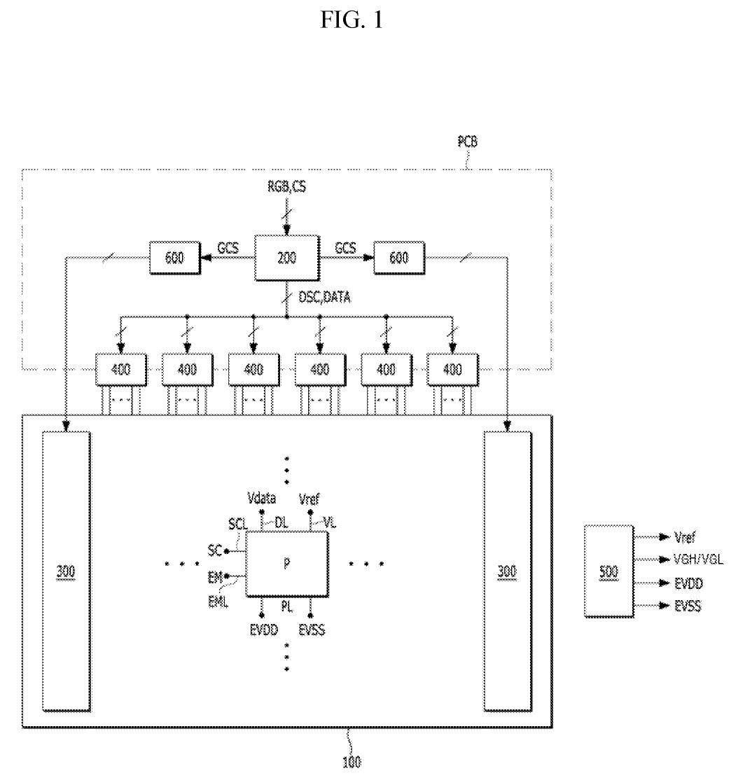

FIG. 1 is a block diagram showing a display device according to an implementation of the present disclosure.

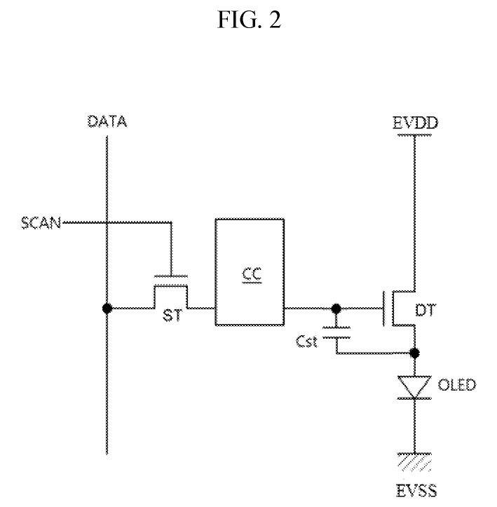

FIG. 2 is a circuit diagram of a pixel included in the display device according to the implementation of the present disclosure.

As shown in FIG. 1, the display device 10 according to the implementation of the present disclosure may include a display panel 100 including a plurality of sub-pixels P, a controller 200, a gate driving circuit 300 configured to supply gate signals to the plurality of sub-pixels P, a data driving circuit 400 configured to supply data signals to the plurality of sub-pixels P, a power supply 500 configured to supply power required for driving to the plurality of sub-pixels P, a level shifter 600 configured to adjust a potential of gate signals applied to the gate driving circuit 300, and a sensing unit (not shown) configured to sense degradation of the plurality of sub-pixels P. In this case, the controller 200, the gate driving circuit 300, the data driving circuit 400, and the sensing unit may be collectively referred to as a controller.

The display panel 100 may include an active area in which the plurality of sub-pixels P is disposed and a non-active area disposed to surround the active area. The gate driving circuit 300 and the data driving circuit 400 may be disposed in the non-active area. Alternatively, the gate driving circuit 300 may be disposed in the active area.

In the display panel 100, a plurality of gate lines SCL and EML and a plurality of data lines DL intersect each other, and each of the plurality of sub-pixels P is connected to the gate lines SCL and EML and the data lines DL. In detail, one sub-pixel P receives a gate signal from the gate driving circuit 300 through the gate lines SCL and EML, receives a data signal from the data driving circuit 400 through the data lines DL, and receives a high-potential driving voltage EVDD and a low-potential driving voltage EVSS from the power supply 500 through a driving voltage line PL.

In this case, the gate lines SCL and EML may include, according to various implementations, a plurality of scan lines SCL configured to supply scan signals SC and a plurality of emission control lines EML configured to supply emission control signals EM. The data lines DL supply a data voltage Vdata. In addition, the plurality of sub-pixels P may further include power lines VL to receive a reference voltage Vref or an initialization voltage Vini.

Thin film transistors (TFTs) constituting the sub-pixels P may be implemented as oxide TFTs including oxide semiconductor layers. Oxide TFTs may be advantageous for enlarging an area of the display panel 100 in consideration of electron mobility and process variations. The present disclosure is not limited thereto, and semiconductor layers of the TFTs may be formed of, for example, amorphous silicon or polysilicon.

In addition, each of the sub-pixels P may include a pixel circuit configured to control driving of a light emitting device OLED. In this case, the light emitting device OLED may include an anode ANO, a cathode CAT, and an emission layer EL disposed between the anode ANO and the cathode CAT.

As shown in FIG. 2, each sub-pixel P may include a switching transistor ST, a driving transistor DT, a compensation circuit CC, the light emitting device OLED, and a storage capacitor Cst.

The light emitting device OLED may operate to emit light according to a driving current formed by the driving transistor DT.

The switching transistor ST may perform a switching operation such that a data signal supplied through the data line DL in response to a scan signal supplied through the scan line SCL is stored as a data voltage in the storage capacitor Cst. The storage capacitor Cst may maintain the data voltage for one frame.

The driving transistor DT may operate such that a constant driving current flows between a high-potential power line EVDD and a low-potential power line EVSS in response to the data voltage stored in the storage capacitor Cst.

The compensation circuit CC is a circuit for compensating a threshold voltage of the driving transistor DT. The compensation circuit CC may include one or more thin film transistors and a capacitor. A configuration of the compensation circuit CC may vary widely depending on a compensation method.

For example, the sub-pixel P shown in FIG. 2 has a 2T1C (2 transistors and 1 capacitor) structure including a switching transistor ST, a driving transistor DT, a storage capacitor Cst, and a light emitting device OLED. When the compensation circuit CC is additionally included, the sub-pixel P may be configured in various structures such as 3T1C, 4T2C, 5T2C, 6T1C, 6T2C, 7T1C, 7T2C, or 8T1C.

The display panel 100 may be implemented as a non-transmissive display panel or a transmissive display panel. The transmissive display panel may be applied to a transparent display device in which an image is displayed on a screen and an object in a background is visible. The display panel 100 may be fabricated as a flexible display panel. The flexible display panel may be implemented as an organic light emitting diode display panel using a plastic substrate.

Each of the sub-pixels P may be divided into a red pixel, a green pixel, and a blue pixel for color implementation. Each of the sub-pixels P may further include a white pixel. Each of the sub-pixels P includes a pixel circuit.

Touch sensors may be disposed on the display panel 100. A touch input may be sensed using separate touch sensors or may be sensed through the sub-pixels P. The touch sensors may be disposed on a screen of the display panel in an on-cell type or an add-on type or may be implemented as in-cell type touch sensors embedded in the display panel 100.

The controller 200 processes image data RGB input from an external source to be suitable for a size and a resolution of the display panel 100 and supplies the processed image data to the data driving circuit 400. The controller 200 generates a gate control signal GCS and a data control signal DCS using timing signals CS input from an external source, for example, a dot clock signal CLK, a data enable signal DE, a horizontal synchronization signal Hsync, and a vertical synchronization signal Vsync. The controller 200 controls the gate driving circuit 300 and the data driving circuit 400 by supplying the generated gate control signal GCS and the generated data control signal DCS to the gate driving circuit 300 and the data driving circuit 400, respectively.

Depending on a device in which the controller 200 is mounted, the controller 200 may be combined with various processors such as a microprocessor, a mobile processor, or an application processor.

The host system may be any one of a television (TV) system, a set-top box, a navigation system, a personal computer (PC), a home theater system, a mobile device, a wearable device, and a vehicle system.

The controller 200 may multiply an input frame frequency by i (i being a positive integer greater than 0) to control operation timing of a display panel driving unit at a frame frequency of “input frame frequency ˟ i” Hz. The input frame frequency is 60 Hz in a national television standards committee (NTSC) scheme and is 50 Hz in a phase-alternating line (PAL) scheme.

The controller 200 generates signals such that the sub-pixels P are driven at various refresh rates. That is, the controller 200 generates signals associated with driving of the sub-pixels P such that the sub-pixels P are driven in a variable refresh rate (VRR) mode or are driven to be switchable between a first refresh rate and a second refresh rate. For example, the controller 200 may drive the sub-pixels P at various refresh rates by changing a speed of a clock signal, generating synchronization signals to create a horizontal blank or a vertical blank, or driving the gate driving circuit 300 in a mask scheme.

The controller 200 generates, based on the timing signals CS received from the host system, a gate control signal GCS for controlling operation timing of the gate driving circuit 300 and a data control signal DCS for controlling operation timing of the data driving circuit 400. The controller 200 controls operation timing of the display panel driving unit to synchronize the gate driving circuit 300 and the data driving circuit 400.

The data driving circuit 400 receives image data DATA and the data control signal DCS from the controller 200. In response to the data control signal DCS from the controller 200, the data driving circuit 400 converts the image data DATA into a gamma-compensated voltage to generate a data voltage Vdata, and supplies the data voltage Vdata to the data lines DL of the display panel 100 in synchronization with a scan signal SC. The data driving circuit 400 may be connected to the data lines of the display panel 100 through a chip-on-glass (COG) process or a tape automated bonding (TAB) process. Although not shown in the drawings, the data driving circuit 400 may be provided with at least one data driving integrated circuit D-IC. For example, the data driving circuit 400 may include one or more data driving integrated circuits D-IC.

The gate driving circuit 300 operates in accordance with the gate control signal GCS input from the level shifter 600 to generate a gate signal, and sequentially supplies the gate signal to the gate lines. The gate driving circuit 300 may be directly formed on a lower substrate of the display panel 100 using a gate driver in panel (GIP) scheme. The gate driving circuit 300 may be formed in an active area of the display panel 100 in which an image is displayed or may be formed in a non-active area outside the active area. The non-active area may include a bezel area or may be identical to the bezel area. In the GIP scheme, the level shifter 600 may be mounted on a printed circuit board (PCB) together with the controller 200.

The power supply 500 generates direct-current (DC) power required to drive a pixel array of the display panel 100 and the display panel driving unit using a DC–DC converter. The DC–DC converter may include a charge pump, a regulator, a buck converter, or a boost converter. The power supply 500 may receive a DC input voltage applied from the host system (not shown), and may generate DC voltages such as gate-on voltages VGL and VEL, gate-off voltages VGH and VEH, a high-potential driving voltage EVDD, and a low-potential driving voltage EVSS. The gate-on voltages VGL and VEL and the gate-off voltages VGH and VEH are supplied to a level shifter (not shown) and the gate driving circuit 300. The high-potential driving voltage EVDD and the low-potential driving voltage EVSS are commonly supplied to the sub-pixels P.

The level shifter 600 boosts a transistor-transistor-logic (TTL) level voltage of the gate control signal GCS input from the controller 200 to a gate high voltage VGH and a gate low voltage VGL capable of driving the TFTs formed in the display panel 100, and supplies the boosted voltages to the gate driving circuit 300. The gate control signal GCS may include a start signal and a clock signal. The plurality of sub-pixels P of the display panel 100 may include at least a first sub-pixel, a second sub-pixel, and a third sub-pixel. The first sub-pixel, the second sub-pixel, and the third sub-pixel may emit light of different colors. For example, the first sub-pixel may be a red pixel, the second sub-pixel may be a green pixel, and the third sub-pixel may be a blue pixel.

The plurality of sub-pixels P may have the same size as each other or may have different sizes from each other. Sizes of the first sub-pixel, the second sub-pixel, and the third sub-pixel may be designed to be different from each other in consideration of, for example, a lifetime or a color balance of the light emitting device OLED included in each of the first sub-pixel, the second sub-pixel, and the third sub-pixel.

The display panel 100 may include an organic light emitting diode display panel, which is a self-emissive display panel.

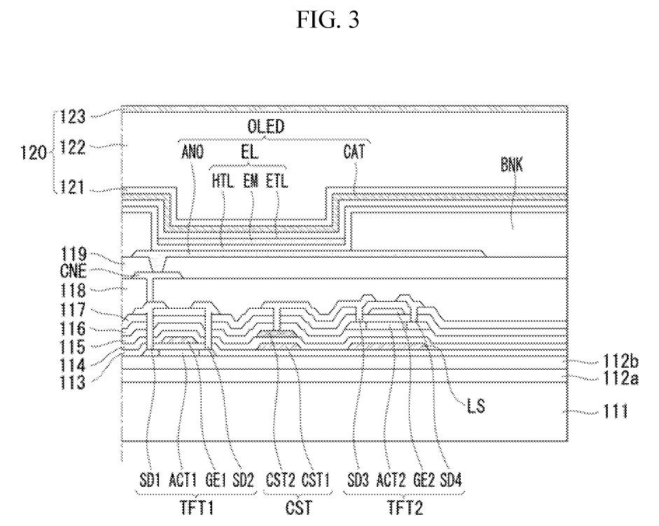

FIG. 3 is a cross-sectional view of one of the sub-pixels disposed in the active area of the display panel according to an implementation of the present disclosure.

As shown in FIG. 3, a plurality of pixels is disposed in the display panel 100. In each pixel area, a light emitting device OLED, transistors TFT1 and TFT2 for driving the light emitting device, a capacitor CST, and an encapsulation layer 120 may be disposed.

The transistors TFT1 and TFT2 may include a silicon thin film transistor including a polycrystalline semiconductor material and an oxide thin film transistor including an oxide semiconductor material. In this case, the thin film transistor including a polycrystalline semiconductor material may be referred to as a polycrystalline thin film transistor TFT1, and the thin film transistor including an oxide semiconductor material may be referred to as an oxide thin film transistor TFT2. For example, the polycrystalline thin film transistor TFT1 may be a transistor connected to the light emitting device OLED, and the oxide thin film transistor TFT2 may be a transistor connected to the capacitor CST.

In another implementation, the thin film transistor including a polycrystalline semiconductor material may be referred to as a polycrystalline thin film transistor TFT2, and the thin film transistor including an oxide semiconductor material may be referred to as an oxide thin film transistor TFT1. For example, the polycrystalline thin film transistor TFT2 may be a transistor connected to the capacitor CST, and the oxide thin film transistor TFT1 may be a transistor connected to the light emitting device OLED.

Hereinafter, the thin film transistor including a polycrystalline semiconductor material will be referred to as a polycrystalline thin film transistor TFT1, and the thin film transistor including an oxide semiconductor material will be referred to as an oxide thin film transistor TFT2.

The substrate 111 may be a glass substrate or a flexible substrate. When the substrate 111 is a flexible substrate, the substrate 111 may be implemented in a multilayer structure in which organic layers and inorganic layers are alternately stacked. For example, the substrate 111 may be formed by alternately stacking organic layers formed of, for example, polyimide and inorganic layers formed of, for example, silicon oxide (SiO₂).

A lower buffer layer 112a may be formed on the substrate 111. The lower buffer layer 112a serves to block infiltration of moisture and the like from an external environment, and may be formed by stacking a plurality of silicon oxide (SiO₂) layers. An auxiliary buffer layer 112b may be further disposed on the lower buffer layer 112a to protect elements from moisture infiltration.

A polycrystalline thin film transistor TFT1 may be formed on the substrate 111. The polycrystalline thin film transistor TFT1 may use a polycrystalline semiconductor as an active layer. The polycrystalline thin film transistor TFT1 may include a first active layer ACT1 including a channel through which electrons or holes move, a first gate electrode GE1, a first source electrode SD1, and a first drain electrode SD2. A first gate insulating layer 113 may be disposed between the first gate electrode GE1 and the first active layer ACT1. The first gate insulating layer 113 may be formed as a single inorganic layer such as a silicon oxide (SiO₂) layer or a silicon nitride (SiNx) layer or may be formed by stacking the inorganic layer multiple times.

The first active layer ACT1 may include a first channel region, a first source region disposed on one side of the first channel region, and a first drain region disposed on the opposite side of the first channel region. The first source region and the first drain region are regions rendered conductive by doping an intrinsic polycrystalline semiconductor material with impurity ions of Group V or Group III, for example, phosphorus (P) or boron (B), at a predetermined concentration. The first channel region serves to maintain the polycrystalline semiconductor material in an intrinsic state, and may provide a path through which electrons or holes move.

According to an implementation, the polycrystalline thin film transistor TFT1 may be implemented in a top-gate structure in which the first gate electrode GE1 is disposed above the first active layer ACT1. Accordingly, a first electrode CST1 included in the capacitor CST and a light-shielding layer LS included in the oxide thin film transistor TFT2 may be formed of the same material as the first gate electrode GE1. By forming the first gate electrode GE1, the first electrode CST1, and the light-shielding layer LS through a single mask process, the number of mask processes may be reduced.

The first gate electrode GE1 may be formed of metal. For example, the first gate electrode GE1 may have a single-layer structure or a multilayer structure, each layer being formed of a material selected from the group consisting of molybdenum (Mo), aluminum (Al), chromium (Cr), gold (Au), titanium (Ti), nickel (Ni), neodymium (Nd), copper (Cu), and alloys thereof. However, the disclosure is not limited thereto.

A first interlayer insulating layer 114 may be disposed on the first gate electrode GE1. The first interlayer insulating layer 114 may be formed of, for example, silicon oxide (SiO₂) or silicon nitride (SiNx).

Each sub-pixel P of the display panel 100 may further include an upper buffer layer 115, a second gate insulating layer 116, and a second interlayer insulating layer 117, which are sequentially disposed on the first interlayer insulating layer 114.

The first source electrode SD1 and the first drain electrode SD2 of the polycrystalline thin film transistor TFT1 may be formed on the second interlayer insulating layer 117. The first source electrode SD1 and the first drain electrode SD2 of the polycrystalline thin film transistor TFT1 may be connected to the first source region and the first drain region of the first active layer ACT1, respectively, through contact holes penetrating the first gate insulating layer 113, the first interlayer insulating layer 114, the upper buffer layer 115, the second gate insulating layer 116, and the second interlayer insulating layer 117.

The upper buffer layer 115 may space the second active layer ACT2 of the oxide thin film transistor TFT2, which is formed of an oxide semiconductor material, apart from the first active layer ACT1 formed of a polycrystalline semiconductor material, and may provide a base on which the second active layer ACT2 is formed.

The oxide thin film transistor TFT2 may be formed on the upper buffer layer 115. The oxide thin film transistor TFT2 may include a second active layer ACT2 formed of an oxide semiconductor material, a second gate electrode GE2 disposed on the second gate insulating layer 116, a second source electrode SD3 disposed on the second interlayer insulating layer 117, and a second drain electrode SD4 disposed on the second interlayer insulating layer 117.

The second active layer ACT2 may be formed of an oxide semiconductor material, and may include an intrinsic second channel region not doped with impurities and may include a second source region and a second drain region that are doped with impurities and thus are rendered conductive.

The oxide thin film transistor TFT2 may further include a light-shielding layer LS disposed under the upper buffer layer 115 and overlapping the second active layer ACT2. The light-shielding layer LS may block light incident through the substrate 111, thereby securing reliability of the oxide thin film transistor TFT2. The light-shielding layer LS may be formed of the same material as the first gate electrode GE1 and may be disposed on an upper surface of the first gate insulating layer 113. The light-shielding layer LS may be electrically connected to the second gate electrode GE2 to form a dual-gate structure.

The second source electrode SD3 and the second drain electrode SD4 may be simultaneously formed of the same material on the second interlayer insulating layer 117 together with the first source electrode SD1 and the first drain electrode SD2, thereby reducing the number of mask processes.

The second gate insulating layer 116 may cover the second active layer ACT2 of the oxide thin film transistor TFT2. Because the second gate insulating layer 116 is formed on the second active layer ACT2 formed of an oxide semiconductor material, the second gate insulating layer 116 may be implemented as an inorganic layer. The second gate insulating layer 116 may be formed of, for example, silicon oxide (SiO₂) or silicon nitride (SiNx).

The second gate electrode GE2 may be formed of metal. For example, the second gate electrode GE2 may have a single-layer structure or a multilayer structure, each layer being formed of a material selected from the group consisting of molybdenum (Mo), aluminum (Al), chromium (Cr), gold (Au), titanium (Ti), nickel (Ni), neodymium (Nd), copper (Cu), and alloys thereof. However, the disclosure is not limited thereto.

A first electrode CST1 may be disposed on the first gate insulating layer 113, and a second electrode CST2 may be disposed on the first interlayer insulating layer 114 so as to overlap the first electrode CST1, thereby implementing the capacitor CST. The first electrode CST1 may be formed of the same material as the light-shielding layer LS and the first gate electrode GE1.

For example, the second electrode CST2 may have a single-layer structure or a multilayer structure, each layer being formed of a material selected from the group consisting of molybdenum (Mo), aluminum (Al), chromium (Cr), gold (Au), titanium (Ti), nickel (Ni), neodymium (Nd), copper (Cu), and alloys thereof.

The capacitor CST may serve to store a data voltage applied through the data line DL for a predetermined period of time. The capacitor CST may include two electrodes corresponding to each other and a dielectric disposed between the two electrodes. The first interlayer insulating layer 114 may be disposed between the first electrode CST1 and the second electrode CST2.

The first electrode CST1 or the second electrode CST2 of the capacitor CST may be electrically connected to the second source electrode SD3 or the second drain electrode SD4 of the oxide thin film transistor TFT2. However, the disclosure is not limited thereto. A connection relationship of the capacitor CST may be changed depending on a sub-pixel driving circuit.

A first planarization layer 118 and the second planarization layer 119 for planarizing a surface may be sequentially disposed on the polycrystalline thin film transistor TFT1, the oxide thin film transistor TFT2, and the capacitor CST. The first planarization layer 118 and the second planarization layer 119 may be organic layers formed of, for example, polyimide or an acrylic resin. A light emitting device OLED may be formed on the second planarization layer 119.

The light emitting device OLED may include an anode ANO, a cathode CAT, and an emission layer EL disposed between the anode ANO and the cathode CAT. In a case in which a sub-pixel driving circuit is implemented to commonly use a low-potential power supply voltage connected to the cathode CAT, the anode ANO is disposed as a separate electrode for each sub-pixel. Alternatively, in a case in which a sub-pixel driving circuit is implemented to commonly use a high-potential power supply voltage, the cathode CAT may be disposed as a separate electrode for each sub-pixel.

The light emitting device OLED may be electrically connected to a driving element via an intermediate electrode CNE disposed on the first planarization layer 118. For example, the anode ANO of the light emitting device OLED and the first source electrode SD1 of the polycrystalline thin film transistor TFT1 may be connected to each other via the intermediate electrode CNE.

The anode ANO may be connected to a portion of the intermediate electrode CNE that is exposed through a contact hole penetrating the second planarization layer 119. The intermediate electrode CNE may be connected to a portion of the first source electrode SD1 that is exposed through a contact hole penetrating the first planarization layer 118.

The intermediate electrode CNE may serve as an intermediary connecting the first source electrode SD1 to the anode ANO. The intermediate electrode CNE may be formed of a conductive material such as copper (Cu), silver (Ag), molybdenum (Mo), or titanium (Ti).

The second planarization layer 119 and the intermediate electrode CNE may be omitted. When the second planarization layer 119 and the intermediate electrode CNE are omitted, the anode ANO may be electrically and directly connected to a portion of the first source electrode SD1 that is exposed through the contact hole penetrating the first planarization layer 118.

When applied to a front-emission organic light emitting diode display device, the anode ANO may be formed in a multilayer structure including a transparent conductive layer and an opaque conductive layer having high reflectance. The transparent conductive layer may be formed of a material having a relatively high work function, such as indium tin oxide (ITO) or indium zinc oxide (IZO). The opaque conductive layer may have a single-layer structure or a multilayer structure, each layer including a material selected from the group consisting of aluminum (Al), silver (Ag), copper (Cu), lead (Pb), molybdenum (Mo), titanium (Ti), and alloys thereof. For example, the anode ANO may be formed in a structure in which a transparent conductive layer, an opaque conductive layer, and a transparent conductive layer are sequentially stacked or may be formed in a structure in which a transparent conductive layer and an opaque conductive layer are sequentially stacked.

A bank layer BNK may be a sub-pixel defining layer that exposes the anode ANO of each sub-pixel. The bank layer BNK may be formed of an opaque material (e.g., black) to prevent optical interference between adjacent sub-pixels. In this case, the bank layer BNK may include a light-shielding material including at least one of a color pigment, organic black, or carbon black.

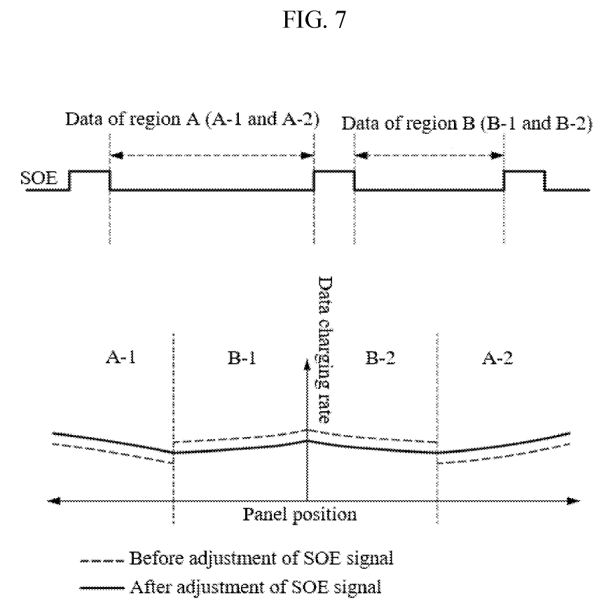

The emission layer EL may be stacked on the anode ANO in an order of a hole-related layer including a hole injection layer HIL and a hole transport layer HTL, an organic emission layer including an emission layer EM, and an electron-related layer including an electron transport layer ETL and an electron injection layer EIL, or in a reverse order. Only the hole transport layer HTL, the emission layer EM, and the electron transport layer ETL are shown in FIG. 7, but the disclosure is not limited thereto.

The cathode CAT may face the anode ANO with the emission layer EL interposed therebetween, and may be formed on an upper surface and side surfaces of the emission layer EL. The cathode CAT may be integrally formed to cover the entire active area. When applied to a front-emission organic light emitting diode display device, the cathode CAT may be implemented as a transparent conductive layer formed of, for example, indium tin oxide (ITO) or indium zinc oxide (IZO). When applied to a back-emission organic light emitting diode display device, the cathode CAT may be implemented as an opaque conductive layer having a single-layer structure or a multilayer structure, each layer including a material selected from the group consisting of aluminum (Al), silver (Ag), copper (Cu), lead (Pb), molybdenum (Mo), titanium (Ti), and alloys thereof. Alternatively, the cathode CAT may be implemented as a semi-transmissive conductive layer having a single-layer structure or a multilayer structure, each layer including a material selected from the group consisting of aluminum (Al), magnesium (Mg), silver (Ag), copper (Cu), lead (Pb), molybdenum (Mo), titanium (Ti), and alloys thereof.

An encapsulation layer 120 for suppressing infiltration of moisture may be additionally disposed on the cathode CAT. The encapsulation layer 120 may block infiltration of external moisture or oxygen toward the emission layer EL, which is vulnerable to moisture and oxygen. To this end, the encapsulation layer 120 may include at least one inorganic encapsulation layer and at least one organic encapsulation layer. However, the disclosure is not limited thereto. The encapsulation layer 120 may include a first encapsulation layer 121, a second encapsulation layer 122, and a third encapsulation layer 123 that are sequentially stacked.

The first encapsulation layer 121 and the third encapsulation layer 123 may be formed of an inorganic insulating material capable of low-temperature deposition, such as silicon nitride (SiNx), silicon oxide (SiOx), silicon oxynitride (SiON), or aluminum oxide (Al₂O₃). Because the first encapsulation layer 121 and the third encapsulation layer 123 are deposited under a low-temperature atmosphere, it may be possible to prevent the emission layer EL, which is vulnerable to a high-temperature atmosphere, from being damaged during a process of depositing the first encapsulation layer 121 and the third encapsulation layer 123.

The second encapsulation layer 122 may serve as a buffer to relieve stress between layers caused by bending of the display device 10, and may planarize interlayer steps. The second encapsulation layer 122 may be disposed on the substrate 111 on which the first encapsulation layer 121 is formed, and may be formed of a non-photosensitive organic insulating material, such as an acrylic resin, an epoxy resin, a phenolic resin, a polyamide resin, a polyimide resin, polyethylene, or silicon oxycarbide (SiOC), or of a photosensitive organic insulating material such as photoreactive acrylic. However, the disclosure is not limited thereto.

Although not shown in the drawings, a touch sensor may be additionally disposed on the encapsulation layer 120.

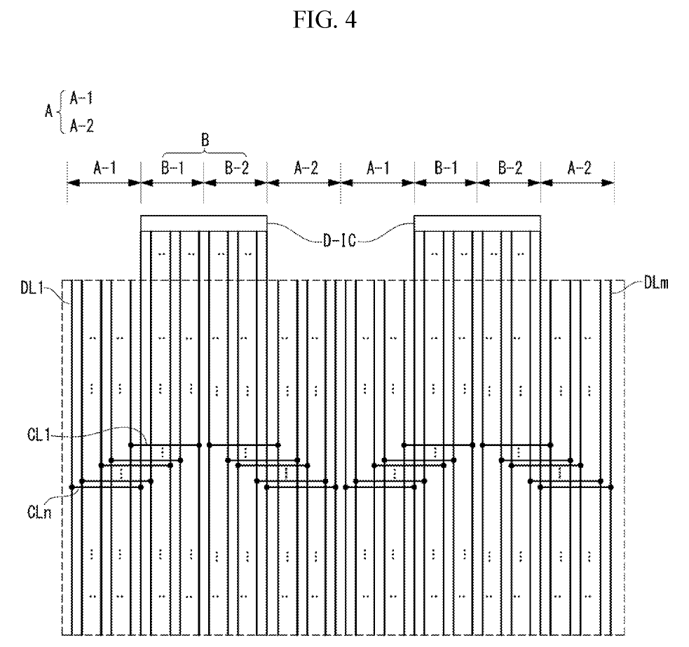

FIG. 4 is a plan view showing data lines and a plurality of data driving integrated circuits according to an implementation of the present disclosure.

The display panel 100 may include a plurality of gate lines (e.g., SCL and EML in FIG. 1) disposed in a first direction and a plurality of data lines DL1 to DLm disposed in a second direction different from the first direction. A plurality of sub-pixels may be disposed at intersections between the plurality of gate lines and the plurality of data lines DL1 to DLm.

The plurality of data lines DL1 to DLm may be driven by at least one data driving integrated circuit D-IC. When the display panel 100 is a large display panel, the plurality of data lines DL1 to DLm may be driven by a plurality of data driving integrated circuits D-IC.

Among the plurality of data lines driven by one data driving integrated circuit D-IC, a first set of data lines (e.g., half of the data lines), which are disposed in a central region B, may be directly connected to the data driving integrated circuit D-IC. A second set of data lines (e.g., the remaining half of the data lines), which are disposed on left and right sides A-1 and A-2, may not be directly connected to the data driving integrated circuit D-IC, and may instead be connected, within the active area, to the first set of data lines (which are directly connected to the data driving integrated circuit D-IC.)

This will be described below in detail.

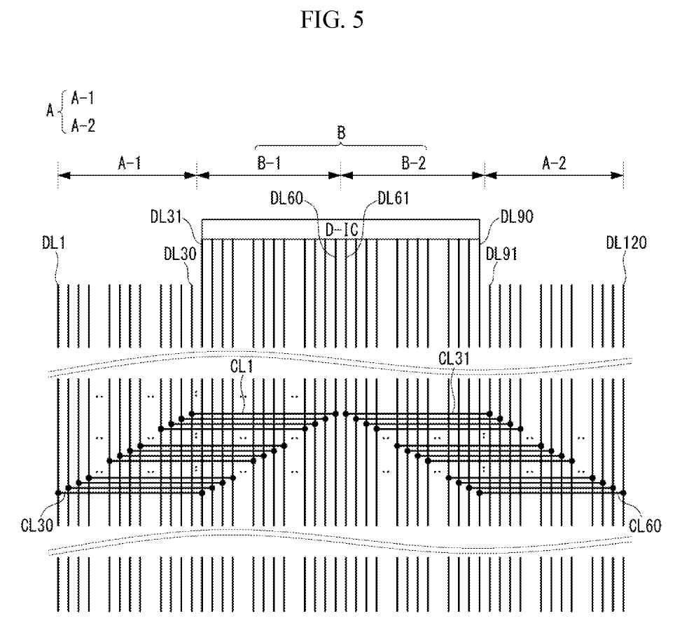

FIG. 5 is a plan view showing a plurality of data lines driven by one data driving integrated circuit D-IC according to an implementation of the present disclosure.

The plurality of data lines driven by one data driving integrated circuit D-IC may be divided into a region A (including regions A-1 and A-2) and a region B (including regions B-1 and B-2). The region B (B-1 and B-2) may include a first set of data lines disposed in a central region among the plurality of data lines driven by one data driving integrated circuit D-IC. The region A (A-1 and A-2) may include a second set of data lines disposed on both sides of the region B (B-1 and B-2) among the plurality of data lines driven by one data driving integrated circuit D-IC. The number of data lines in the second set of data lines disposed in the region A (A-1 and A-2) and the number of data lines in the first set of data lines disposed in the region B (B-1 and B-2) may be equal to each other.

The first set of data lines disposed in the region B (B-1 and B-2) may be directly connected to the data driving integrated circuit D-IC. The second set of data lines disposed in the region A (A-1 and A-2) may not be directly connected to the data driving integrated circuit D-IC, and instead may be connected, within the active area, to the first set of data lines disposed in the region B (B-1 and B-2). The second set of data lines disposed in the region A (A-1 and A-2) may be connected (e.g., in one-to-one correspondence) to the first set of data lines disposed in the region B (B-1 and B-2) via a plurality of connection lines CL1 to CL60.

In order to minimize RC delay variation of the second set of data lines disposed in the region A (A-1 and A-2), the plurality of connection lines CL1 to CL60 may connect, at intermediate portions of the data lines, the second set of data lines disposed in the region A (A-1 and A-2) to the first set of data lines disposed in the region B (B-1 and B-2), e.g., in one-to-one correspondence. The plurality of connection lines CL1 to CL60 may have the same length.

This will be described below in more detail.

For convenience of description, FIG. 5 will be described on the assumption that the number of data lines driven by one data driving integrated circuit is 120.

The region A (A-1 and A-2) may be divided into a region A-1 (A-1) and a region A-2 (A-2), and the region B (B-1 and B-2) may be divided into a region B-1 (B-1) and a region B-2 (B-2). The same number of data lines may be disposed in the region A-1 (A-1), the region A-2 (A-2), the region B-1 (B-1), and the region B-2 (B-2).

In this example, among the 120 data lines DL1 to DL120 driven by one data driving integrated circuit, 30 data lines DL1 to DL30 from a 1^{st} data line DL1 to a 30^{th} data line DL30 correspond to the region A-1 (A-1), 30 data lines DL31 to DL60 from a 31^{st} data line DL31 to a 60^{th} data line DL60 correspond to the region B-1 (B-1), 30 data lines DL61 to DL90 from a 61^{st} data line DL61 to a 90^{th} data line DL90 correspond to the region B-2 (B-2), and 30 data lines DL91 to DL120 from a 91^{st} data line DL91 to a 120^{th} data line DL120 correspond to the region A-2 (A-2).

The 30 data lines DL31 to DL60 from the 31^{st} data line DL31 to the 60^{th} data line DL60 in the region B-1 (B-1) and the 30 data lines DL61 to DL90 from the 61^{st} data line DL61 to the 90^{th} data line DL90 in the region B-2 (B-2) are directly connected to the data driving integrated circuit D-IC.

The 30 data lines DL1 to DL30 from the 1^{st} data line DL1 to the 30^{th} data line DL30 in the region A-1 (A-1) and the 30 data lines DL91 to DL120 from the 91^{st} data line DL91 to the 120^{th} data line DL120 in the region A-2 (A-2) are not directly connected to the data driving integrated circuit D-IC.

Instead, the 30 data lines DL1 to DL30 from the 1^{st} data line DL1 to the 30^{th} data line DL30 in the region A-1 (A-1) are electrically connected, in one-to-one correspondence, to the 30 data lines DL31 to DL60 from the 31^{st} data line DL31 to the 60^{th} data line DL60 in the region B-1 (B-1) via the connection lines CL1 to CL30.

The 30 data lines DL91 to DL120 from the 91^{st} data line DL91 to the 120^{th} data line DL120 in the region A-2 (A-2) are electrically connected, in one-to-one correspondence, to the 30 data lines DL61 to DL90 from the 61^{st} data line DL61 to the 90^{th} data line DL90 in the region B-2 (B-2) via the connection lines CL31 to CL60.

For example, the 1^{st} data line DL1 in the region A-1 (A-1) is electrically connected to the 31^{st} data line DL31 in the region B-1 (B-1) via the connection line CL1, the 2^{nd} data line DL2 in the region A-1 (A-1) is electrically connected to the 32^{nd} data line DL32 in the region B-1 (B-1) via the connection line CL2, the 29^{th} data line DL29 in the region A-1 (A-1) is electrically connected to the 59^{th} data line DL59 in the region B-1 (B-1) via the connection line CL29, and the 30^{th} data line DL30 in the region A-1 (A-1) is electrically connected to the 60^{th} data line DL60 in the region B-1 (B-1) via the connection line CL30.

In this manner, the 30 data lines DL1 to DL30 in the region A-1 (A-1) are connected, in one-to-one correspondence, to the 30 data lines DL31 to DL60 in the region B-1 (B-1) via the connection lines CL1 to CL30.

The 91^{st} data line DL91 in the region A-2 (A-2) is electrically connected to the 61^{st} data line DL61 in the region B-2 (B-2) via the connection line CL31, the 92^{nd} data line DL92 in the region A-2 (A-2) is electrically connected to the 62^{nd} data line DL62 in the region B-2 (B-2) via the connection line CL32, the 119^{th} data line DL119 in the region A-2 (A-2) is electrically connected to the 89^{th} data line DL89 in the region B-2 (B-2) via the connection line CL59, and the 120^{th} data line DL120 in the region A-2 (A-2) is electrically connected to the 90^{th} data line DL90 in the region B-2 (B-2) via the connection line CL60.

In this manner, the 30 data lines DL91 to DL120 in the region A-2 (A-2) are connected, in one-to-one correspondence, to the 30 data lines DL61 to DL90 in the region B-2 (B-2) via the connection lines CL31 to CL60.

Because the 60 data lines disposed in the region A (A-1 and A-2) are connected, in one-to-one correspondence, to the 60 data lines disposed in the region B (B-1 and B-2) via the 60 connection lines CL1 to CL60 through the above-described method, the 60 connection lines CL1 to CL60 have the same length. In addition, the 60 connection lines CL1 to CL60 are disposed at central portions of the data lines. Accordingly, RC delay variation caused by the 60 connection lines CL1 to CL60 may be minimized.

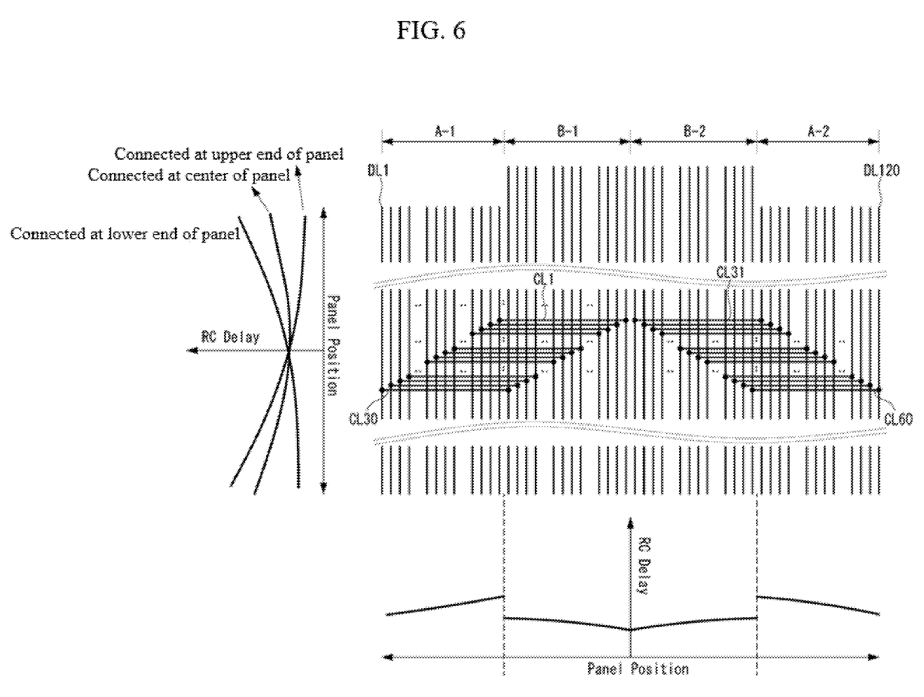

FIG. 6 is a plan view showing RC delay variation in a vertical direction and a horizontal direction of a plurality of data lines driven by one data driving integrated circuit D-IC according to an implementation of the present disclosure.

RC delay variation may occur differently depending on positions at which the connection lines CL1 to CL60 described with reference to FIG. 5 connect the data lines DL1 to DL30 and DL91 to DL120 disposed in the region A (A-1 and A-2) to the data lines DL31 to DL90 disposed in the region B (B-1 and B-2).

That is, as shown in FIG. 6, when viewed in the vertical direction of the display panel, if the connection lines CL1 to CL60 connecting the data lines DL1 to DL30 and DL91 to DL120 disposed in the region A (A-1 and A-2) to the data lines DL31 to DL90 disposed in the region B (B-1 and B-2) are disposed at an upper portion or a lower portion of the display panel, RC delay variation increases compared to when the connection lines CL1 to CL60 are disposed at a central portion of the display panel.

In addition, when viewed in the horizontal direction of the display panel, in the region A-1 (A-1), the number of intersections between the connection lines and the data lines gradually increases toward a right side, so RC delay increases. Contrary to the region A-1 (A-1), in the region B-1 (B-1), the number of intersections between the connection lines and the data lines gradually decreases toward the right side, so RC delay decreases. Further, the region A-2 (A-2) and the region B-2 (B-2) have tendencies opposite those of the region A-1 (A-1) and the region B-1 (B-1). Accordingly, a boundary between the region A (A-1 and A-2) and the region B (B-1 and B-2) may be visually recognized due to RC delay variation. Therefore, it is advantageous that the 60 connection lines CL1 to CL60 be disposed at central portions of the data lines DL1 to DL120 in a longitudinal direction.

Even when, in order to minimize RC delay variation of the data lines, the region B (B-1 and B-2), which is directly connected to the data driving integrated circuit D-IC, is disposed in a central region among the plurality of data lines, and the connection lines CL1 to CL60 connecting the data lines DL1 to DL30 and DL91 to DL120 disposed in the region A (A-1 and A-2) to the data lines DL31 to DL90 disposed in the region B (B-1 and B-2) are disposed at central portions of the data lines, as described with reference to FIG. 4, RC delay variation between the data lines in the region A (A-1 and A-2) and the data lines in the region B (B-1 and B-2) may still occur. For example, RC delay of the data lines in the region A (A-1 and A-2) is greater than RC delay of the data lines in the region B (B-1 and B-2).

RC delay variation between the data lines in the region A (A-1 and A-2) and the data lines in the region B (B-1 and B-2) affects a charging rate of the data voltage, and thus causes luminance variation in the display panel.

FIG. 7 is a view showing data input times and data charging rates of the data lines in the region A and the region B according to an implementation of the present disclosure.

In order to prevent the occurrence of luminance variation in the display panel due to RC delay variation between the data lines in the region A (A-1 and A-2) and the data lines in the region B (B-1 and B-2), as shown in FIG. 7, a source output enable (SOE) signal for outputting a data signal from the data driving integrated circuit D-IC is adjusted such that data input times of the data lines in the region A (A-1 and A-2) are longer than data input times of the data lines in the region B (B-1 and B-2).

As shown in FIG. 7, when the data input times of the data lines in the region A (A-1 and A-2) and the data input times of the data lines in the region B (B-1 and B-2) are the same as each other (“Before Adjustment of SOE Signal”), a difference in data charging rate occurs between the data lines in the region A-1 (A-1), the region A-2 (A-2), the region B-1 (B-1), and the region B-2 (B-2), and thus luminance variation may occur in the display panel.

However, when the data input times of the data lines in the region A-1 (A-1) and the region A-2 (A-2) are set to be longer than the data input times of the data lines in the region B-1 (B-1) and the region B-2 (B-2) (“After Adjustment of SOE Signal”), the data charging rate smoothly varies over the entire display panel, and luminance variation of the display panel is not visually recognized.

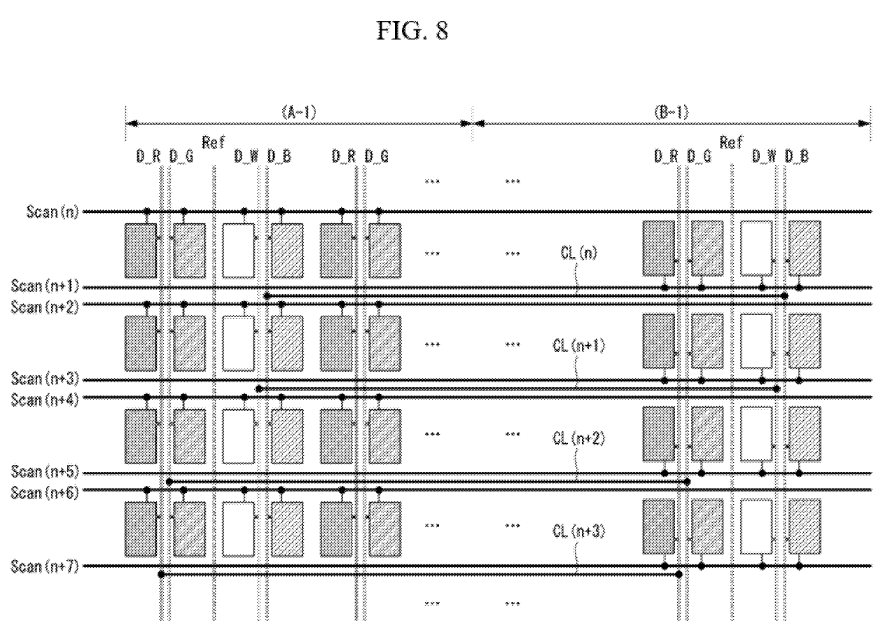

FIG. 8 is a view showing a layout of gate lines, data lines, and sub-pixels in the region A-1 and the region B-1 according to an implementation of the present disclosure.

A plurality of gate lines Scan(n) to Scan(n+7) may be disposed across the region A-1 (A-1) and the region B-1 (B-1) in a first direction. A plurality of data lines D_R, D_G, D_W, and D_B may be disposed in each of the region A-1 and the region B-1 in a second direction different from the first direction. A plurality of sub-pixels may be disposed at intersections between the plurality of gate lines Scan(n) to Scan(n+7) and the plurality of data lines D_R, D_G, D_W, and D_B.

In addition, a plurality of sub-pixels may be disposed between a (4k-3)^{th} gate line and a (4k-2)^{th} gate line and between a (4k-1)^{th} gate line and a 4k^{th} gate line among the plurality of gate lines. No sub-pixels are disposed between the (4k-2)^{th} gate line and the (4k-1)^{th} gate line and between the 4k^{th} gate line and a (4k+1)^{th} gate line among the plurality of gate lines. In this case, k is a natural number.

For example, a plurality of sub-pixels may be disposed between the gate line Scan(n) and the gate line Scan(n+1) and between the gate line Scan(n+2) and the gate line Scan(n+3) among the plurality of gate lines Scan(n) to Scan(n+7). No sub-pixels are disposed between the gate line Scan(n+1) and the gate line Scan(n+2) and between the gate line Scan(n+3) and the gate line Scan(n+4).

In the horizontal direction, two sub-pixels may be disposed between a pair of data lines D_R and D_G and a pair of data lines D_W and D_B. No sub-pixels are disposed between the pair of data lines D_R and D_G and between the pair of data lines D_W and D_B.

A reference voltage line Ref may be disposed between the two sub-pixels disposed between the pair of data lines D_R and D_G and the pair of data lines D_W and D_B. The reference voltage line Ref may be disposed parallel to the data lines D_R, D_G, D_W, and D_B.

The respective sub-pixels in the region A-1 (A-1) may be driven by odd-numbered gate lines Scan(n), Scan(n+2), Scan(n+4), …, and the respective sub-pixels in the region B-1 (B-1) may be driven by even-numbered gate lines Scan(n+1), Scan(n+3), Scan(n+5), …. However, the disclosure is not limited thereto. The respective sub-pixels in the region A-1 (A-1) may be driven by the even-numbered gate lines Scan(n+1), Scan(n+3), Scan(n+5), …, and the respective sub-pixels in the region B-1 (B-1) may be driven by the odd-numbered gate lines Scan(n), Scan(n+2), Scan(n+4), ….

Each of the connection lines CL(n) to CL(n+3) may electrically connect one data line of the same color in the region A-1 (A-1) to one data line of the same color in the region B-1 (B-1). For example, the connection lines CL(n) to CL(n+3) may electrically connect the red data line D_R in the region A-1 (A-1) to the red data line D_R in the region B-1 (B-1), may electrically connect the green data line D_G in the region A-1 (A-1) to the green data line D_G in the region B-1 (B-1), may electrically connect the white data line D_W in the region A-1 (A-1) to the white data line D_W in the region B-1 (B-1), and may electrically connect the blue data line D_B in the region A-1 (A-1) to the blue data line D_B in the region B-1 (B-1).

Due to the above-described connection structure of the connection lines CL(n) to CL(n+3), the connection lines CL(n) to CL(n+3) may be disposed at different positions in a vertical direction, each being shifted by one pixel relative to an adjacent one.

FIG. 8 shows a configuration in which one connection line (one of CL(n) to CL(n+3)) is disposed between the gate line Scan(n+1) and the gate line Scan(n+2), between the gate line Scan(n+3) and the gate line Scan(n+4), and between the gate line Scan(n+5) and the gate line Scan(n+6). However, the disclosure is not limited thereto. For example, one connection line CL(n) may be disposed between the gate line Scan(n+1) and the gate line Scan(n+2), no connection line may be disposed between the gate line Scan(n+3) and the gate line Scan(n+4), one connection line CL(n+1) may be disposed between the gate line Scan(n+5) and the gate line Scan(n+6), and no connection line may be disposed between the gate line Scan(n+7) and the gate line Scan(n+8).

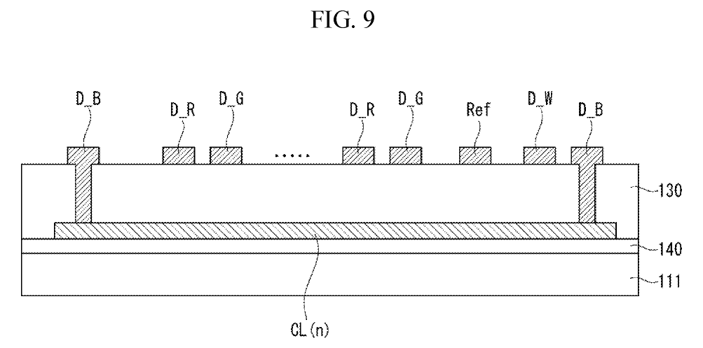

FIG. 9 is a schematic cross-sectional view taken along the connection line CL(n) shown in FIG. 8.

As shown in FIG. 9, a first insulating layer 140 may be disposed on a substrate 111. The first insulating layer 140 may include at least one of the lower buffer layer 112a, the auxiliary buffer layer 112b, or the first gate insulating layer 113 described with reference to FIG. 3.

The connection line CL(n) may be disposed on the first insulating layer 140. The connection line CL(n) may be formed of the same material as the first gate electrode GE1 described with reference to FIG. 3.

A second insulating layer 130 may be disposed on the first insulating layer 140 including the connection line CL(n). The second insulating layer 130 may include at least one of the first interlayer insulating layer 114, the upper buffer layer 115, the second gate insulating layer 116, or the second interlayer insulating layer 117 described with reference to FIG. 3.

A plurality of data lines D_R, D_G, D_W, and D_B and a reference voltage line Ref may be disposed on the second insulating layer 130 in a direction perpendicular to the connection line CL(n).

Contact holes may be formed in the second insulating layer 130 so that both end portions of the connection line CL(n) are exposed through the contact holes. The blue data line D_B in the region A-1 (A-1) and the blue data line D_B in the region B-1 (B-1) may be electrically connected to the respective end portions of the connection line CL(n) through the contact holes.

In this manner, each of the connection lines CL(n) to CL(n+3) may be formed of the same material as the first gate electrode GE1 or the gate line described with reference to FIG. 3. However, the connection lines CL(n) to CL(n+3) according to the present disclosure are not limited thereto. The connection lines CL(n) to CL(n+3) according to the present disclosure may be formed of a material different from that of the data lines D_R, D_G, D_W, and D_B. For example, the connection lines CL(n) to CL(n+3) may be formed of the same material as any one of the intermediate electrode CNE, the anode ANO, and the cathode CAT described with reference to FIG. 3.

FIG. 8 illustrates arrangements of the gate lines, the data lines, and the sub-pixels in the region A-1 and the region B-1. Arrangements of the gate lines, the data lines, and the sub-pixels in the region A-2 and the region B-2 are the same as those described with reference to FIG. 8. That is, arrangements of the elements in the region A-2 may be the same as those in the region A-1, and arrangements of the elements in the region B-2 may be the same as those in the region B-1.

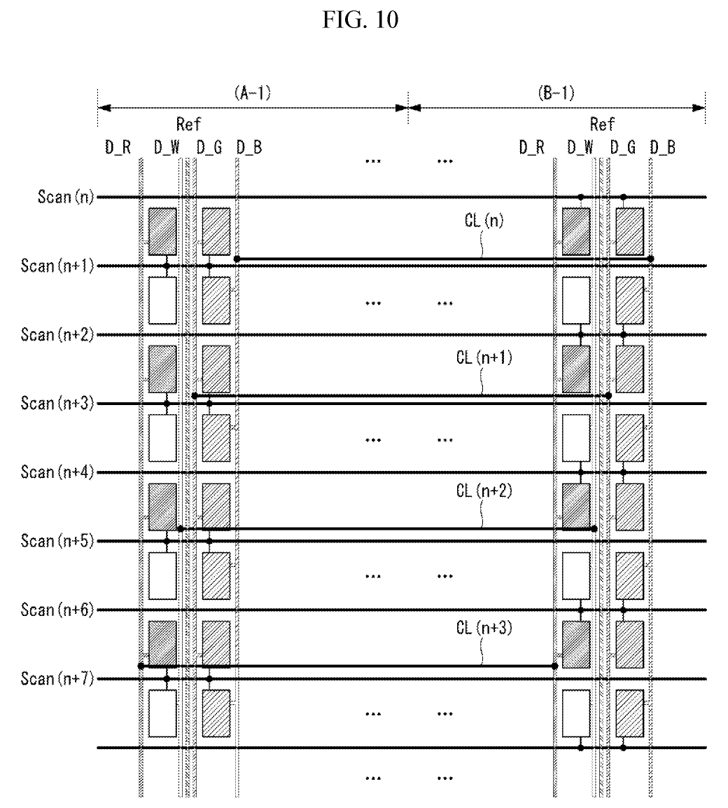

FIG. 10 is a view showing a layout of gate lines, data lines, and sub-pixels in the region A-1 and the region B-1 according to another implementation of the present disclosure.

A plurality of gate lines Scan(n) to Scan(n+7) may be disposed across the region A-1 (A-1) and the region B-1 (B-1) in a first direction. A plurality of data lines D_R, D_G, D_W, and D_B may be disposed in each of the region A-1 and the region B-1 in a second direction different from the first direction. A plurality of sub-pixels may be disposed at intersections between the plurality of gate lines Scan(n) to Scan(n+7) and the plurality of data lines D_R, D_G, D_W, and D_B.

In addition, a plurality of sub-pixels may be disposed between respective gate lines among the plurality of gate lines Scan(n) to Scan(n+7). Red and green sub-pixels may be disposed between a (2k-1)^{th} gate line and a 2k^{th} gate line, and white and blue sub-pixels may be disposed between the 2k^{th} gate line and a (2k+1)^{th} gate line among the plurality of gate lines. In this case, k is a natural number. Alternatively, white and blue sub-pixels may be disposed between the (2k-1)^{th} gate line and the 2k^{th} gate line, and red and green sub-pixels may be disposed between the 2k^{th} gate line and the (2k+1)^{th} gate line among the plurality of gate lines. However, the disclosure is not limited thereto. Arrangement of the sub-pixels may be variously modified.

For example, red and green sub-pixels may be disposed between the gate line Scan(n) and the gate line Scan(n+1), between the gate line Scan(n+2) and the gate line Scan(n+3), between the gate line Scan(n+4) and the gate line Scan(n+5), and between the gate line Scan(n+6) and the gate line Scan(n+7), and white and blue sub-pixels may be disposed between the gate line Scan(n+1) and the gate line Scan(n+2), between the gate line Scan(n+3) and the gate line Scan(n+4), and between the gate line Scan(n+5) and the gate line Scan(n+6), among the plurality of gate lines Scan(n) to Scan(n+7).

In the horizontal direction, one sub-pixel may be disposed between a (4k-3)^{th} data line D_R and a (4k-2)^{th} data line D_W and between respective gate lines among the gate lines Scan(n) to Scan(n+7), and one sub-pixel may be disposed between a (4k-1)^{th} data line D_G and a 4k^{th} data line D_B and between respective gate lines among the gate lines Scan(n) to Scan(n+7). No sub-pixels are disposed between the (4k-2)^{th} data line D_W and the (4k-1)^{th} data line D_G and between the 4k^{th} data line D_B and a (4k+1)^{th} data line D_R.

Reference voltage lines Ref may be disposed between the (4k-2)^{th} data line D_W and the (4k-1)^{th} data line D_G and between the 4k^{th} data line D_B and the (4k+1)^{th} data line D_R. The reference voltage linen Ref may be disposed parallel to the data lines D_R, D_G, D_W, and D_B.

The respective sub-pixels in the region A-1 (A-1) may be driven by even-numbered gate lines Scan(n+1), Scan(n+3), Scan(n+5), …, and the respective sub-pixels in the region B-1 (B-1) may be driven by odd-numbered gate lines Scan(n), Scan(n+2), Scan(n+4), …. However, the disclosure is not limited thereto. The respective sub-pixels in the region A-1 (A-1) may be driven by the odd-numbered gate lines Scan(n), Scan(n+2), Scan(n+4), …, and the respective sub-pixels in the region B-1 (B-1) may be driven by the even-numbered gate lines Scan(n+1), Scan(n+3), Scan(n+5), ….

Each of the connection lines CL(n) to CL(n+3) may electrically connect one data line of the same color in the region A-1 (A-1) to one data line of the same color in the region B-1 (B-1). For example, the connection lines CL(n) to CL(n+3) may electrically connect the red data line D_R in the region A-1 (A-1) to the red data line D_R in the region B-1 (B-1), may electrically connect the green data line D_G in the region A-1 (A-1) to the green data line D_G in the region B-1 (B-1), may electrically connect the white data line D_W in the region A-1 (A-1) to the white data line D_W in the region B-1 (B-1), and may electrically connect the blue data line D_B in the region A-1 (A-1) to the blue data line D_B in the region B-1 (B-1).

FIG. 10 illustrates arrangements of the gate lines, the data lines, and the sub-pixels in the region A-1 and the region B-1. Arrangements of the gate lines, the data lines, and the sub-pixels in the region A-2 and the region B-2 are the same as those described with reference to FIG. 10. That is, arrangements of the elements in the region A-2 may be the same as those in the region A-1, and arrangements of the elements in the region B-2 may be the same as those in the region B-1.

The cross-sectional structure of each of the connection lines CL(n) to CL(n+3) described with reference to FIG. 10 may be the same as that described with reference to FIG. 9.

As described above, according to implementations of the present disclosure, among a plurality of data lines driven by one data driving integrated circuit, half of the data lines, which are disposed in a central region, are directly connected to the data driving integrated circuit. The remaining half of the data lines, which are disposed on left and right sides, are not directly connected to the data driving integrated circuit, and are electrically connected to the data lines directly connected to the data driving integrated circuit. Accordingly, a narrow bezel may be implemented.

In addition, data input times of sub-pixels connected to the data lines directly connected to the data driving integrated circuit are set to be shorter than data input times of sub-pixels connected to the remaining data lines not directly connected to the data driving integrated circuit. Accordingly, it may be possible to prevent visual recognition of luminance variation between the data lines directly connected to the data driving integrated circuit and the remaining data lines not directly connected to the data driving integrated circuit.

As is apparent from the above description, according to the present disclosure, among a plurality of data lines driven by one data driving integrated circuit, some data lines disposed in a central region are directly connected to the data driving integrated circuit. The remaining data lines disposed on left and right sides are not directly connected to the data driving integrated circuit, and are electrically connected to the data lines directly connected to the data driving integrated circuit.

Accordingly, a narrow bezel may be implemented.

In addition, data input times of sub-pixels connected to the data lines directly connected to the data driving integrated circuit are set to be shorter than data input times of sub-pixels connected to the remaining data lines not directly connected to the data driving integrated circuit.

Accordingly, luminance variation between the data lines directly connected to the data driving integrated circuit and the remaining data lines not directly connected to the data driving integrated circuit may be prevented from being visually recognized.

The effects achievable through the present disclosure are not limited to the above-mentioned effects, and various other effects may be directly or implicitly disclosed in the above detailed description of the present disclosure.

While the present disclosure has been described above, the present disclosure is not limited to the above-described implementations and the accompanying drawings, and it will be apparent to those skilled in the art that various alterations, modifications, and changes can be made without departing from the technical spirit of the disclosure.

What is claimed is:

1. A display device comprising:
a display panel including a plurality of gate lines and a plurality of data lines; and
at least one data driving integrated circuit configured to supply a data signal to each of the plurality of data lines,
wherein, among data lines driven by one data driving integrated circuit of the at least one data driving circuit:
(i) a first set of data lines disposed in a central region among the data lines are directly connected to the one data driving integrated circuit, and
(ii) a second set of data lines disposed on left and right sides among the data lines are not directly connected to the one data driving integrated circuit, and are electrically connected, via a plurality of connection lines within an active area, to the first set of data lines.

2. The display device according to claim 1, wherein the plurality of connection lines all have a same length.

3. The display device according to claim 1, wherein the plurality of connection lines intersect the plurality of data lines in a middle portion of a longitudinal length of the plurality of data lines.

4. The display device according to claim 1, wherein each of the plurality of connection lines interconnects data lines implementing a same color.

5. The display device according to claim 1, wherein the first set of data lines correspond to half of the plurality of data lines, and the second set of data lines correspond to a remaining half of the plurality of data lines.

6. The display device according to claim 5, wherein the first set of data lines consist of (i) first data lines disposed in a region B-1 in the central region and (ii) second data lines disposed in a region B-2 in the central region, wherein the second set of data lines consist of (i) third data lines disposed in a region A-1 adjacent to the region B-1 and (ii) fourth data lines disposed in a region A-2 adjacent to the region B-2, wherein the third data lines disposed in the region A-1 are electrically connected to the first data lines disposed in the region B-1 via first connection lines among the plurality of connection lines, and wherein the fourth data lines disposed in the region A-2 are electrically connected to the second data lines disposed in the region B-2 via second connection lines among the plurality of connection lines.

7. The display device according to claim 6, wherein a number of the third data lines disposed in the region A-1, a number of the fourth data lines disposed in the region A-2, a number of the first data lines disposed in the region B-1, and a number of the second data lines disposed in the region B-2 are the same.

8. The display device according to claim 6, wherein data input times of the third data lines disposed in the region A-1 and the fourth data lines disposed in the region A-2 are longer than data input times of the first data lines disposed in the region B-1 and the second data lines disposed in the region B-2.

9. The display device according to claim 6, wherein a plurality of sub-pixels is disposed between a (4k-3)^{th} gate line and a (4k-2)^{th} gate line and between a (4k-1)^{th} gate line and a 4k^{th} gate line among the plurality of gate lines, and wherein sub-pixels are not disposed between the (4k-2)^{th} gate line and the (4k-1)^{th} gate line and between the 4k^{th} gate line and a (4k+1)^{th} gate line among the plurality of gate lines.

10. The display device according to claim 9, wherein two sub-pixels are disposed between a first pair of data lines and a second pair of data lines, and
wherein sub-pixels are not disposed between the first pair of data lines and between the second pair of data lines.

11. The display device according to claim 10, wherein sub-pixels in the region A-1 and the region A-2 are driven by even-numbered gate lines, and wherein sub-pixels in the region B-1 and the region B-2 are driven by odd-numbered gate lines.

12. The display device according to claim 10, wherein sub-pixels in the region A-1 and the region A-2 are driven by odd-numbered gate lines, and wherein sub-pixels in the region B-1 and the region B-2 are driven by even-numbered gate lines.

13. The display device according to claim 10, further comprising a plurality of reference voltage lines disposed between the two sub-pixels.

14. The display device according to claim 6, wherein a plurality of sub-pixels is disposed between respective gate lines among the plurality of gate lines, wherein one sub-pixel is disposed between a (4k-3)^{th} data line and a (4k-2)^{th} data line among the plurality of data lines and between respective gate lines, and one sub-pixel is disposed between a (4k-1)^{th} data line and a 4k^{th} data line and between respective gate lines, and wherein sub-pixels are not disposed between the (4k-2)^{th} data line and the (4k-1)^{th} data line and between the 4k^{th} data line and a (4k+1)^{th} data line.

15. The display device according to claim 14, wherein sub-pixels in the region A-1 and the region A-2 are driven by even-numbered gate lines, and wherein sub-pixels in the region B-1 and the region B-2 are driven by odd-numbered gate lines.

16. The display device according to claim 14, wherein sub-pixels in the region A-1 and the region A-2 are driven by odd-numbered gate lines, and wherein sub-pixels in the region B-1 and the region B-2 are driven by even-numbered gate lines.

17. The display device according to claim 14, further comprising a plurality of reference voltage lines disposed between the (4k-2)^{th} data line and the (4k-1)^{th} data line and between the 4k^{th} data line and the (4k+1)^{th} data line.

18. The display device according to claim 1, wherein the plurality of connection lines is formed of a same material as the plurality of gate lines.
